(19) United States
(12) Patent Application Publication
(10) Pub. No.: US 2026/0282283 A1
(43) Pub. Date: Sep. 17, 2026

(54) METHOD AND SYSTEM FOR CONTROLLING TEMPERATURE OF COOLANT LIQUID IN LIQUID COOLING HEAT DISSIPATION

(71) Applicants: INVENTEC (PUDONG) TECHNOLOGY CORPORATION, Shanghai (CN); INVENTEC CORPORATION, Taipei City (TW)

(72) Inventors: Chien-Ming LEE, Taipei City (TW); Kai-Yang TUNG, Taipei City (TW)

(73) Assignees: INVENTEC (PUDONG) TECHNOLOGY CORPORATION, Shanghai (CN); INVENTEC CORPORATION, Taipei City (TW)

(21) Appl. No.: 19/325,022

(22) Filed: Sep. 10, 2025

(30) Foreign Application Priority Data
Mar. 11, 2025 (CN) 202510285206.1

(51) Int. Cl. H05K 7/20

(52) U.S. Cl. CPC H05K 7/20281; H05K 7/20254; H05K 7/20263

(57) ABSTRACT

A method for controlling temperature of coolant liquid in liquid cooling heat dissipation, applicable for a heat exchanger that supplies coolant liquid and executed by a controller, the method includes: performing proportional-integral-derivative computation based on a preset temperature and an outlet liquid temperature of the heat exchanger at a first time point to obtain a first speed control parameter, generating a compensation value based on a recovered liquid temperature at the first time point and the recovered liquid temperature at a second time point of the heat exchanger, and controlling the fan speed of the heat exchanger based on the compensation value and the first speed control parameter. A system for controlling temperature of coolant liquid in liquid cooling heat dissipation, applicable for a heat exchanger supplying coolant liquid and including with at least one fan, includes a first temperature sensor, a second temperature sensor, and a controller.

### CROSS-REFERENCE TO RELATED APPLICATIONS

This non-provisional application claims priority under 35 U.S.C. § 119 (a) on Patent Application No(s). 202510285206.1 filed in People Republic of China on Mar. 11, 2025, the entire contents of which are hereby incorporated by reference.

### BACKGROUND

### 1. Technical Field

This disclosure relates to a method and system for controlling temperature of coolant liquid in liquid cooling heat dissipation.

### 2. Related Art

Direct liquid-to-chip (DLC) heat dissipation solution is a high-efficiency liquid cooling heat dissipation technology, primarily used for cooling of the electronic components such as processors and graphics processing units. The direct liquid-to-chip heat dissipation system of the computing side mainly employs a cold plate, while the cooling distribution unit (CDU) may be classified, depending on the type of cooling equipment, into a liquid-to-air (L2A) CDU and a liquid-to-liquid (L2L) CDU.

In existing L2A CDU products, fan control is primarily achieved by using a proportional-integral-derivative (PID) controller to control the outlet water temperature. By performing proportional, integral, and derivative computations on the temperature error, the rotational speed value of the fan is determined. The airflow generated by the fan may then remove heat from the hot water within the heat exchanger and output cooled water. However, using a PID controller alone for water temperature control adjusts fan response solely through parameter tuning. Increasing parameter values may cause fan oscillation and excessive energy consumption, thereby failing to meet energy-saving design requirements. Conversely, decreasing parameter values may cause slow fan response, which fails to meet cooling requirements.

### SUMMARY

Accordingly, this disclosure provides a method and system for controlling temperature of coolant liquid in liquid cooling heat dissipation.

According to an embodiment of this disclosure, a system for controlling temperature of coolant liquid in liquid cooling heat dissipation, applicable for a heat exchanger supplying coolant liquid and including at least one fan, comprises a first temperature sensor, a second temperature sensor and a controller, wherein the controller is connected to the first temperature sensor and the second temperature sensor. The first temperature sensor is configured to be disposed at a liquid outlet of the heat exchanger to obtain an outlet liquid temperature. The second temperature sensor is configured to be disposed at a liquid recover inlet of the heat exchanger to obtain a recovered liquid temperature. The controller is configured to perform proportional-integral-derivative computation to obtain a first speed control parameter based on a preset temperature and the outlet liquid temperature of the heat exchanger at a first time point to obtain a first speed control parameter, generate a compensation value based on the recovered liquid temperature at the first time point and the recovered liquid temperature at a second time point of the heat exchanger, and control a fan speed of the at least one fan based on the compensation value and the first speed control parameter.

According to an embodiment of this disclosure, a method for controlling temperature of coolant liquid in liquid cooling heat dissipation, applicable for a heat exchanger supplying coolant liquid and executed by a controller, comprises: performing proportional-integral-derivative computation to obtain a first speed control parameter based on a preset temperature and an outlet liquid temperature of the heat exchanger at a first time point; generating a compensation value based on a recovered liquid temperature at the first time point and the recovered liquid temperature at a second time point of the heat exchanger; and controlling a fan speed of the heat exchanger based on the compensation value and the first speed control parameter.

In view of the above description, the method and system for controlling temperature of coolant liquid in liquid cooling heat dissipation of the present disclosure may serve as a liquid temperature compensator for a PID controller, and may maintain stable fan control and effectively control the outlet liquid temperature to prevent an oscillation in fan rotational speed that may result in energy waste, and may satisfy the antipyretic requirements of the product.

### BRIEF DESCRIPTION OF THE DRAWINGS

The present disclosure will become more fully understood from the detailed description given hereinbelow and the accompanying drawings which are given by way of illustration only and thus are not limitative of the present disclosure and wherein:

FIG. 1 is a functional block diagram illustrating a system for controlling temperature of coolant liquid and applicable environment of the same according to an embodiment of the present disclosure;

FIG. 2 is a schematic diagram illustrating the arrangement of a system for controlling temperature of coolant liquid and applicable environment of the same according to an embodiment of the present disclosure;

FIG. 3 is a flowchart illustrating a method for controlling temperature of coolant liquid in liquid cooling heat dissipation according to an embodiment of the present disclosure;

FIG. 4 is a flowchart illustrating a process for generating a compensation value in a method for controlling temperature of coolant liquid in liquid cooling heat dissipation according to an embodiment of the present disclosure;

FIG. 5 is a flowchart illustrating a process for controlling fan rotational speed in a method for controlling temperature of coolant liquid in liquid cooling heat dissipation according to an embodiment of the present disclosure; and

FIG. 6 is a schematic diagram illustrating liquid temperature and fan control results in a method for controlling temperature of coolant liquid in liquid cooling heat dissipation according to an embodiment of the present disclosure.

### DETAILED DESCRIPTION

In the following detailed description, for purposes of explanation, numerous specific details are set forth in order to provide a thorough understanding of the disclosed embodiments. According to the description, claims and the drawings disclosed in the specification, one skilled in the art may easily understand the concepts and features of the present invention. The following embodiments further illustrate various aspects of the present invention, but are not meant to limit the scope of the present invention.

The method and system for controlling temperature of coolant liquid in liquid cooling heat dissipation described below may be applicable to a heat exchanger supplying cooling liquid and comprising at least one fans.

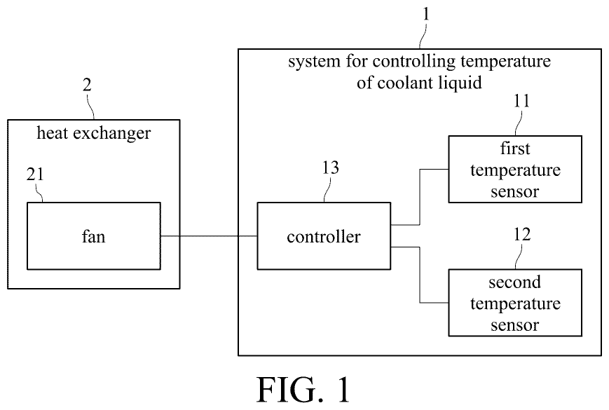

Please refer to FIG. 1, which is a functional block diagram illustrating a system for controlling temperature of coolant liquid and applicable environment of the same according to an embodiment of the present disclosure. As shown in FIG. 1, the coolant liquid temperature control system 1 includes a first temperature sensor 11, a second temperature sensor 12, and a controller 13. The controller 13 is connected via a wired or wireless connection to the first temperature sensor 11 and the second temperature sensor 12, and the controller 13 is connected to a fan 21 of a heat exchanger 2. The fan 21 may be configured to generate an airflow to further remove heat from the liquid inside the heat exchanger 2, thereby enabling the heat exchanger 2 to output cooled coolant. In FIG. 1, the fan 21 is illustratively depicted as one fan; however, the present disclosure is not limited thereto, the number of the fan 21 may be two or more than two, and a plurality of fans 21 may be individually or collectively connected to the controller 13. For example, the heat exchanger 2 may have nine fans 21, each connected to the controller 13, respectively.

The first temperature sensor 11 is configured to be disposed at a liquid outlet of the heat exchanger 2 to obtain an outlet liquid temperature. For example, the first temperature sensor 11 may be an immersion-type resistance temperature detector (RTD), a thermocouple, a thermistor, an infrared temperature sensor, or a semiconductor temperature sensor. Specifically, the first temperature sensor 11 may be a temperature sensor of a commercially available liquid-to-air cooling distribution unit (L2A CDU) control system, configured to continuously sense the outlet liquid temperature and transmit the temperature results to the controller 13.

The second temperature sensor 12 is configured to be disposed at a liquid recover inlet of the heat exchanger 2 to obtain a recovered liquid temperature. For example, the second temperature sensor 12 may be an immersion-type resistance temperature detector, a thermocouple, a thermistor, an infrared temperature sensor, or a semiconductor temperature sensor, and the second temperature sensor 12 may be the same as or different from the first temperature sensor 11, the present disclosure is not limited thereto. Specifically, the second temperature sensor 12 may have a fixed sampling period, may obtain the recovered liquid temperature at different time points, and transmit recovered liquid temperatures of multiple time points to the controller 13.

The controller 13 is configured to perform a proportional-integral-derivative (PID) computation to obtain a first speed control parameter based on a preset temperature and the outlet liquid temperature of the heat exchanger 2 at a first time point, generate a compensation value based on the recovered liquid temperature at the first time point and the recovered liquid temperature at a second time point of the heat exchanger 2, and control a fan speed of the at least one fan 21 based on the compensation value and the first speed control parameter. For example, the controller 13 may include one or more processors, such as a central processing unit (CPU), graphics processing unit (GPU), microcontroller, programmable logic controller (PLC), or other processors capable of signal processing. The first speed control parameter may be a fan speed value determined by the controller 13 based on the outlet liquid temperature sensed by the first temperature sensor 11, i.e., a fan speed value generated by the controller 13 through proportional-integral-derivative computation on the temperature error. The first time point is later than the second time point, and the compensation value may be used to accelerate or reduce the fan speed of the fan 21.

In an embodiment, when a sampling period of the controller 13 receiving the recovered liquid temperature from the second temperature sensor 12 is greater than or equal to one second, the interval between the first time point and the second time point is at least three times the sampling period. Specifically, the interval between the first time point and the second time point may range from approximately three seconds to five seconds.

In an embodiment, the controller 13 may obtain the recovered liquid temperatures at the first time point and the second time point through the second temperature sensor 12, and generate the compensation value by multiplying a temperature difference between the recovered liquid temperature at the first time point and the recovered liquid temperature at the second time point by a preset proportion parameter in the proportional-integral-derivative computation. Please refer to Equation (1), Equation (1) may represent a calculation formula used by the controller 13 to generate the compensation value, wherein Kₚ is the controller parameter, y₂ is the recovered liquid temperature, Δt is the sampling period, and n is a positive integer greater than one.

$${u}_{compensator} = {K}_{p} [ {y}_{2} ( k ) - {y}_{2} ( k - n Δ t ) ] \qquad Equation ( 1 )$$

In an embodiment, the controller 13 may add the compensation value to the first speed control parameter to obtain a second speed control parameter, and control the rotational speed of at least one fan 21 based on the second speed control parameter. Please refer to Equation (2), Equation (2) may represent a calculation formula employed by the controller 13 to control the fan speed, wherein PID represents the proportional-integral-derivative computation formula of the controller 13, Kₚ is a controller parameter, y₁ is the outlet liquid temperature, y₂ is the recovered liquid temperature, Δt is the sampling period, and n is a positive integer greater than one.

$$u = PID ( {y}_{1} ) + {K}_{p} ( {y}_{2} ( k ) - {y}_{2} ( k - n Δ t ) ) \qquad Equation ( 2 )$$

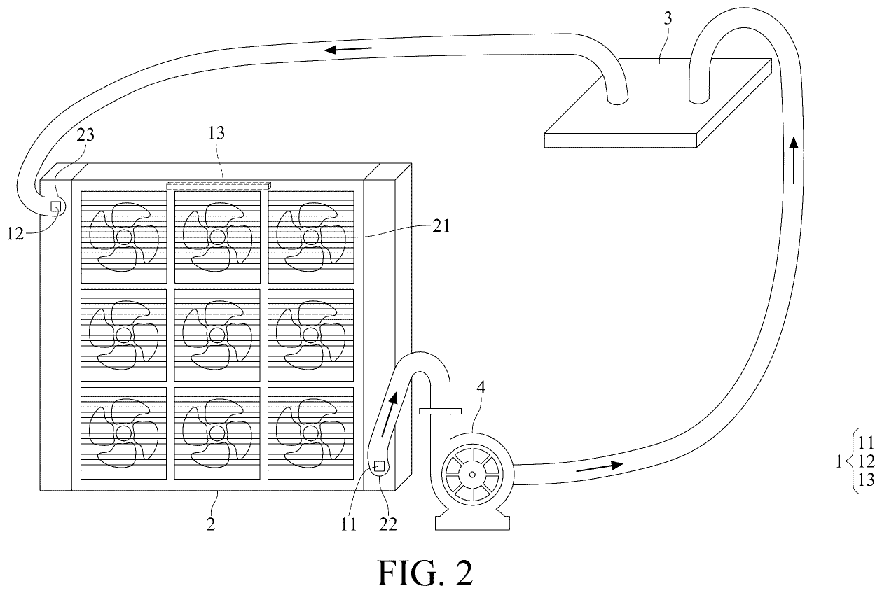

Please refer to FIG. 2, which is a schematic diagram illustrating the arrangement of a system for controlling temperature of coolant liquid and applicable environment of the same according to an embodiment of the present disclosure. As shown in FIG. 2, a first temperature sensor 11 of the coolant liquid temperature control system 1 may be disposed at a liquid outlet 22 of a heat exchanger 2, a second temperature sensor 12 may be disposed at a liquid recover inlet 23 of the heat exchanger 2, and liquid circulates for liquid cooling heat dissipation between the heat exchanger 2 and a cold plate 3 through a pump 4. The controller 13 is connected to the first temperature sensor 11 and the second temperature sensor 12, and may be connected to at least one fan 21 of the heat exchanger 2 and configured to control the fan speed. The implementation devices, functions, and operational principles of the first temperature sensor 11, the second temperature sensor 12, and the controller 13 are the same as described with respect to FIG. 1 and will not be repeated here. The pump 4 is an optionally provided component. FIG. 2 illustratively depicts the heat exchanger 2 including nine fans 21; however, the number of fans 21 in the heat exchanger 2 may be fewer than nine or greater than nine. In an embodiment, the controller 13 may control the rotational speed of all fans 21 simultaneously. In another embodiment, the controller 13 may control only a part of the plurality of fans 21 in the heat exchanger 2 to adjust the rotational speed of such part of fans 21.

The heat exchanger 2 may include at least one fan 21, the liquid outlet 22, and the liquid inlet 23, and may be configured to remove heat from the liquid to the air. The cold plate 3 is disposed to connect to an output pipeline of the heat exchanger 2 to receive the coolant and exchange heat with an external chip, and the coolant circulates back to the heat exchanger 2 after absorbing heat in the cold plate 3. The pump 4 is disposed between the heat exchanger 2 and the cold plate 3 and configured to provide circulation of the coolant. In an embodiment, the heat exchanger 2 may be an air-cooled heat exchanger (L2A heat exchanger), and the fans 21 may be independent and not included in the heat exchanger 2. The heat exchanger 2, the pump 4 and the fans 21 may be implemented for an air-cooled CDU, and linked with load through the cold plate 3 to form a DLC heat dissipation solution. The controller 13 may be connected to the air-cooled CDU via a wired or wireless connection to control the rotational speed of the fans 21. In an embodiment, the system for controlling temperature of coolant liquid in liquid cooling heat dissipation may include the coolant liquid temperature control system 1, the heat exchanger 2, the cold plate 3 and the pump 4. FIG. 2 illustratively shows the relative disposition positions of the components of the coolant liquid temperature control system 1 with other components, but is not limited thereto, and the controller 13 may alternatively be disposed below the heat exchanger 2 or in another location.

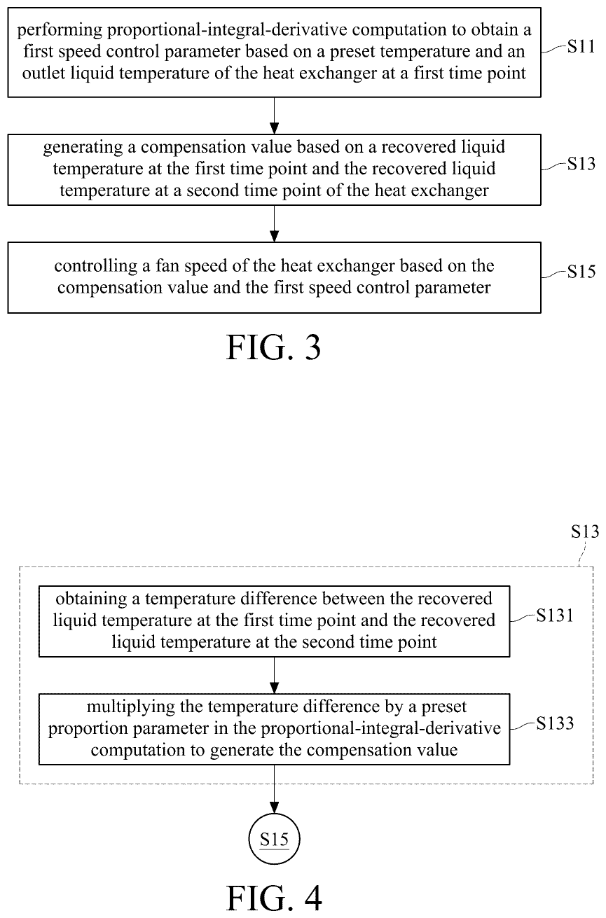

Please refer to FIG. 3, which is a flowchart illustrating a method for controlling temperature of coolant liquid in liquid cooling heat dissipation according to an embodiment of the present disclosure. As shown in FIG. 3, the method for controlling temperature of coolant liquid in liquid cooling heat dissipation includes step S11: performing proportional-integral-derivative computation to obtain a first speed control parameter based on a preset temperature and an outlet liquid temperature of the heat exchanger at a first time point; step S13: generating a compensation value based on a recovered liquid temperature at the first time point and the recovered liquid temperature at a second time point of the heat exchanger; and step S15: controlling a fan speed of the heat exchanger based on the compensation value and the first speed control parameter. The method for controlling temperature of coolant liquid in liquid cooling heat dissipation may be applicable to the coolant liquid temperature control system 1 in liquid cooling heat dissipation shown in FIG. 1 and FIG. 2. Hereinafter, the method for controlling temperature of coolant liquid in liquid cooling heat dissipation shown in FIG. 3 will be described by way of example with reference to the coolant liquid temperature control system 1 shown in FIG. 1.

In step S11, the controller 13 performs proportional-integral-derivative computation to obtain the first speed control parameter based on the preset temperature and the outlet liquid temperature of the heat exchanger 2 at the first time point. Specifically, the controller 13 may compute the first speed control parameter by applying proportional, integral, and derivative calculations to the temperature difference between the outlet liquid temperature and the preset temperature, and the first speed control parameter may correspond to a rotational speed value of the fan 21.

In step S13, the controller 13 generates the compensation value based on the recovered liquid temperature at the first time point and the recovered liquid temperature at the second time point of the heat exchanger 2. In an embodiment, when a sampling period of the controller 13 receiving the recovered liquid temperature from the second temperature sensor 12 is greater than or equal to one second, the interval between the first time point and the second time point is at least three times the sampling period. Specifically, the interval between the first time point and second time point may range from three seconds to five seconds. To further illustrate step S13, please refer to FIG. 1, FIG. 3, and FIG. 4 together, wherein FIG. 4 is a flowchart illustrating a process for generating a compensation value in a method for controlling temperature of coolant liquid in liquid cooling heat dissipation according to an embodiment of the present disclosure.

As shown in FIG. 4, step S13 of FIG. 3 may include step S131: obtaining a temperature difference between the recovered liquid temperature at the first time point and the recovered liquid temperature at the second time point; and step S133: multiplying the temperature difference by a preset proportion parameter in the proportional-integral-derivative computation to generate the compensation value.

In step S131, the controller 13 obtains the temperature difference between the recovered liquid temperature at the first time point and the recovered liquid temperature at the second time point. For example, the recovered liquid temperature at the first time point may be 39° C., the recovered liquid temperature at the second time point may be 26° C., and the temperature difference between the recovered liquid temperature at the first time point and the recovered liquid temperature at the second time point obtained by the controller 13 is 13° C.

In step S133, the controller 13 multiplies the temperature difference by the preset proportion parameter in the proportional-integral-derivative computation to generate the compensation value. Specifically, the preset proportion parameter in the proportional-integral-derivative computation may correspond to the Kₚ parameter described in the aforementioned Equation (2), and the compensation value generated by multiplying the temperature difference by the preset proportion parameter may be a temperature value or a fan speed control value.

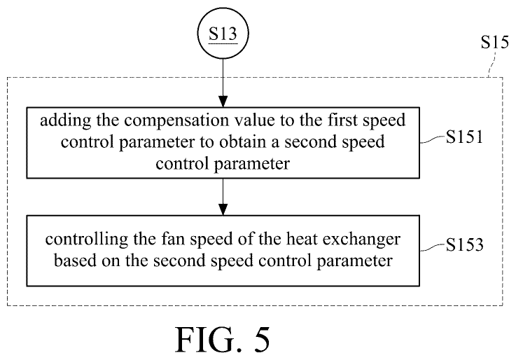

After obtaining the compensation value in step S13, in step S15 of FIG. 3, the controller 13 controls the rotational speed of at least one fan 21 of the heat exchanger 2 according to the compensation value and the first speed control parameter. To further illustrate step S15, please refer to FIG. 1, FIG. 3, and FIG. 5, wherein FIG. 5 is a flowchart illustrating a process for controlling fan speed in a method for controlling temperature of coolant liquid in liquid cooling heat dissipation according to an embodiment of the present disclosure.

As shown in FIG. 5, step S15 of FIG. 3 may include step S151: adding the compensation value to the first speed control parameter to obtain a second speed control parameter; and step S153: controlling the fan speed of the heat exchanger based on the second speed control parameter.

In step S151, the controller 13 adds the compensation value to the first speed control parameter to obtain the second speed control parameter. Specifically, the first speed control parameter may be the same as, or different from, a fan speed control parameter of a commercial L2A CDU control system, and the addition of the compensation value to the first speed control parameter by the controller 13 may be regarded as a compensator for the commercial L2A CDU control system.

In step S153, the controller 13 controls the fan speed of the heat exchanger 2 based on the second speed control parameter. Specifically, since the second speed control parameter incorporates a control factor derived from the recovered liquid temperature with respect to the first speed control parameter, the controller 13 may perform preemptive fan speed adjustments in the heat exchanger 2 to prevent excessive temperature overshoot of the liquid during instantaneous chip load increases, thereby avoiding delays in cooling.

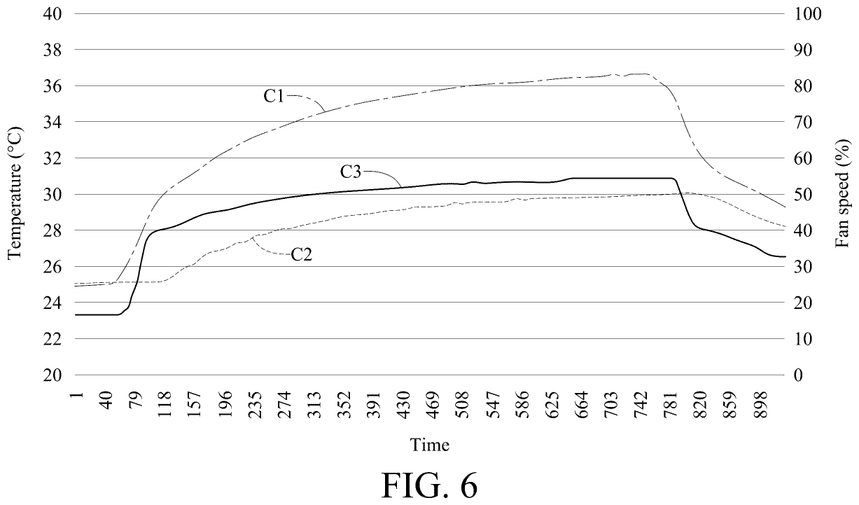

Please refer to FIG. 6 in combination with step S15 of FIG. 3, FIG. 6 is a schematic diagram illustrating liquid temperature and fan control results in a method for controlling temperature of coolant liquid in liquid cooling heat dissipation according to an embodiment of the present disclosure. As shown in FIG. 6, the recovered liquid temperature curve C1 has a temperature range between 25° C. and 37° C. After passing through the heat exchanger 2, the liquid is cooled, and at the liquid outlet of the heat exchanger 2, the first temperature sensor 11 measures the outlet liquid temperature to produce an outlet liquid temperature curve C2. The outlet liquid temperature curve C2 has a temperature range between 25° C. and 30° C. and may be maintained below 30° C. A fan speed curve C3 shows a relatively smooth profile without significant oscillations. Specifically, during the cooling process of the liquid in the heat exchanger 2 by the fan 21, the actual sensing data from the second temperature sensor 12 forms the recovered liquid temperature curve C1, the actual sensing data from the first temperature sensor 11 forms the outlet liquid temperature curve C2, and then the controller 13 generates the relatively stable fan speed curve C3 via the recovered liquid temperature and outlet liquid temperature.

For example, the recovered liquid refers to the heated liquid that directly flows back to the CDU from the water-cooling plate after absorbing heat from a chip. The thermal response of the recovered liquid temperature is significantly faster than that of the outlet liquid temperature. Whether during a load increase of the chip in which the recovered liquid temperature rises after heating, or during a load decrease of the chip in which the liquid temperature drops, the recovered liquid temperature responds more quickly than the outlet liquid temperature. Thus, by leveraging the fast response characteristic of the recovered liquid temperature as a compensator for controlling the outlet liquid temperature, the performance of the L2A CDU outlet liquid temperature control may be effectively improved, and achieving the effect of energy-saving control.

In view of the above description, the method and system for controlling temperature of coolant liquid in liquid cooling heat dissipation of the present disclosure may serve as a liquid temperature compensator for a PID controller, and may maintain stable fan control and effectively control the outlet liquid temperature to prevent an oscillation in fan rotational speed that may result in energy waste, and may satisfy the antipyretic requirements of the product.

In an embodiment, the method and system for controlling temperature of coolant liquid in liquid cooling heat dissipation of the present invention may be applied to a server, and the server may be configured for artificial intelligence (AI) computing, edge computing, or may be implemented as a 5G server, cloud server, or Internet-of-Vehicles server.

What is claimed is:

1. A method for controlling temperature of coolant liquid in liquid cooling heat dissipation, applicable for a heat exchanger supplying coolant liquid and executed by a controller, and the method comprising:
performing proportional-integral-derivative computation to obtain a first speed control parameter based on a preset temperature and an outlet liquid temperature of the heat exchanger at a first time point;
generating a compensation value based on a recovered liquid temperature at the first time point and the recovered liquid temperature at a second time point of the heat exchanger; and
controlling a fan speed of the heat exchanger based on the compensation value and the first speed control parameter.

2. The method for controlling temperature of coolant liquid in liquid cooling heat dissipation according to claim 1, wherein generating the compensation value based on the recovered liquid temperature at the first time point and the recovered liquid temperature at the second time point of the heat exchanger comprises:
obtaining a temperature difference between the recovered liquid temperature at the first time point and the recovered liquid temperature at the second time point; and
multiplying the temperature difference by a preset proportion parameter in the proportional-integral-derivative computation to generate the compensation value.

3. The method for controlling temperature of coolant liquid in liquid cooling heat dissipation according to claim 1, wherein controlling the fan speed of the heat exchanger based on the compensation value and the first speed control parameter comprises:
adding the compensation value to the first speed control parameter to obtain a second speed control parameter; and
controlling the fan speed of the heat exchanger based on the second speed control parameter.

4. The method for controlling temperature of coolant liquid in liquid cooling heat dissipation according to claim 1, wherein an interval between the first time point and the second time point is at least three times of a sampling period of the recovered liquid when the sampling period of the recovered liquid temperature is greater than or equal to 1 second.

5. The method for controlling temperature of coolant liquid in liquid cooling heat dissipation according to claim 1, wherein an interval between the first time point and the second time point is 3 seconds to 5 seconds.

6. A system for controlling temperature of coolant liquid in liquid cooling heat dissipation, applicable for a heat exchanger supplying coolant liquid and including at least one fan, comprising:
a first temperature sensor configured to be disposed at a liquid outlet of the heat exchanger to obtain an outlet liquid temperature;
a second temperature sensor configured to be disposed at a liquid recover inlet of the heat exchanger to obtain a recovered liquid temperature; and
a controller connected to the first temperature sensor and the second temperature sensor, configured to perform proportional-integral-derivative computation to obtain a first speed control parameter based on a preset temperature and the outlet liquid temperature of the heat exchanger at a first time point, generate a compensation value based on the recovered liquid temperature at the first time point and the recovered liquid temperature at a second time point of the heat exchanger, and control a fan speed of the at least one fan based on the compensation value and the first speed control parameter.

7. The system for controlling temperature of coolant liquid in liquid cooling heat dissipation according to claim 6, wherein the controller is configured to obtain a temperature difference between the recovered liquid temperature at the first time point and the recovered liquid temperature at the second time point, and multiply the temperature difference by a preset proportion parameter in the proportional-integral-derivative computation to generate the compensation value.

8. The system for controlling temperature of coolant liquid in liquid cooling heat dissipation according to claim 6, wherein the controller is configured to add the compensation value to the first speed control parameter to obtain a second speed control parameter, and control the fan speed of the at least one fan based on the second speed control parameter.

9. The system for controlling temperature of coolant liquid in liquid cooling heat dissipation according to claim 6, wherein an interval between the first time point and the second time point is at least three times of a sampling period of the recovered liquid when the sampling period of the recovered liquid temperature is greater than or equal to 1 second.

10. The system for controlling temperature of coolant liquid in liquid cooling heat dissipation according to claim 6, wherein an interval between the first time point and the second time point is 3 seconds to 5 seconds.
